(19) United States
(12) Patent Application Publication
(10) Pub. No.: US 2025/0294998 A1
(43) Pub. Date: Sep. 18, 2025

(54) DISPLAY SUBSTRATE, DISPLAY PANEL, AND DISPLAY DEVICE

(71) Applicants: Beijing BOE Technology Development Co., Ltd., Beijing (CN); BOE Technology Group Co., Ltd., Beijing (CN)

(72) Inventors: Haidong Wu, Beijing (CN); Yansong Li, Beijing (CN); Xiaobo Du, Beijing (CN); Lixia Qiu, Beijing (CN); Tong Wu, Beijing (CN)

(21) Appl. No.: 18/703,817

(22) PCT Filed: Apr. 25, 2023
(86) PCT No.: PCT/CN2023/090620

§ 371 Date: Apr. 23, 2024

(51) Int. Cl. H10K 59/80; H10K 59/122

(52) U.S. Cl. CPC H10K 59/80516; H10K 59/122

(57) ABSTRACT

A display substrate, a display panel and a display device are provided. The display substrate includes: a base substrate; a light emitting functional layer on base substrate; a first electrode layer on side of light emitting functional layer away from base substrate; a metal suppression layer on side of first electrode layer away from base substrate; an auxiliary electrode layer on side of first electrode layer away from base substrate; and a light emitting device on base substrate; the light emitting device includes a light emitting portion and a first electrode in first electrode layer; the metal suppression layer includes a metal suppression structure, and an orthographic projection of light emitting portion on base substrate is located within an orthographic projection of metal suppression structure on base substrate; and the auxiliary electrode layer includes an auxiliary electrode electrically connected to first electrode and spaced apart from metal suppression structure.

### CROSS-REFERENCE TO RELATED APPLICATION

This application is a Section 371 National Stage Application of International Application No. PCT/CN2023/090620, filed on Apr. 25, 2023, entitled “DISPLAY SUBSTRATE, DISPLAY PANEL, AND DISPLAY DEVICE”, the content of which is hereby incorporated by reference in its entirety.

### TECHNICAL FIELD

The present disclosure relates to the field of display technology, and in particular to a display substrate, a display panel, and a display device.

### BACKGROUND

At present, electroluminescent display devices are increasingly important in a display industry. In particular, OLED display devices have been widely promoted and applied in recent years due to advantages of high color gamut, bendability, and fast response time, etc.

In addition, in recent years, QLED display devices have received attentions of many companies and researchers due to advantages of low manufacturing costs and high color gamut. When an OLED display device or a QLED display device is applied in a large-sized or medium-sized product, if a top emitting structure is used, there are high requirements on a transmittance of a cathode located on a light exit side. For example, a thickness of the cathode needs to be less than 20 nm. However, a thin cathode has a high resistance, which may lead to a significant difference in brightness at different positions of a display product, and affect a visual experience of the display product.

### SUMMARY

In view of the above problems, the present disclosure provides a display substrate, a display panel, and a display device.

According to a first aspect of the present disclosure, a display substrate is provided, including: a base substrate; a light emitting functional layer provided on the base substrate; a first electrode layer provided on a side of the light emitting functional layer away from the base substrate; a metal suppression layer provided on a side of the first electrode layer away from the base substrate; an auxiliary electrode layer provided on a side of the first electrode layer away from the base substrate; and a light emitting device provided on the base substrate; where the light emitting device includes a light emitting portion and a first electrode located in the first electrode layer; the metal suppression layer includes a metal suppression structure, and an orthographic projection of the light emitting portion on the base substrate is located within an orthographic projection of the metal suppression structure on the base substrate; and the auxiliary electrode layer includes an auxiliary electrode electrically connected to the first electrode and spaced apart from the metal suppression structure.

According to the embodiments of the present disclosure, the light emitting functional layer includes a pixel defining layer, the pixel defining layer includes a pixel opening and a first defining portion surrounding the pixel opening, and the light emitting portion of the light emitting device is located in the pixel opening; and the auxiliary electrode at least partially surrounds the metal suppression structure, and an orthographic projection of the auxiliary electrode on the base substrate is located within an orthographic projection of the first defining portion on the base substrate.

According to the embodiments of the present disclosure, the metal suppression structure includes a first middle portion and a first edge portion surrounding the first middle portion, and the first edge portion overlaps with the first defining portion in a thickness direction of the display substrate; and a thickness of the auxiliary electrode is greater than or equal to a thickness of the metal suppression structure, and the auxiliary electrode overlaps at least partially with the first edge portion in the thickness direction of the display substrate.

According to the embodiments of the present disclosure, a ratio of the thickness of the auxiliary electrode to the thickness of the metal suppression structure is in a range from 1:1 to 100:1.

According to the embodiments of the present disclosure, the metal suppression structure includes a first middle portion and a first edge portion surrounding the first middle portion, and the first edge portion overlaps with the first defining portion in a thickness direction of the display substrate; and a thickness of the auxiliary electrode is less than a thickness of the metal suppression structure, and the auxiliary electrode is spaced apart from the first edge portion in the thickness direction of the display substrate

According to the embodiments of the present disclosure, a ratio of the thickness of the auxiliary electrode to the thickness of the metal suppression structure is in a range from 1:20 to 2:5.

According to the embodiments of the present disclosure, the first edge portion includes a first inclined portion, a first angle is formed between a surface of the first inclined portion on a side away from the base substrate and the first electrode, a second angle is formed between a surface adjacent to the first inclined portion of the auxiliary electrode and the first electrode, and the first angle is substantially the same as the second angle.

According to the embodiments of the present disclosure, a cross-sectional shape of the metal suppression structure in a direction perpendicular to the base substrate includes a trapezoid or an inverted trapezoid.

According to the embodiments of the present disclosure, a thickness of the auxiliary electrode is negatively correlated with a thickness of the metal suppression structure, a first distance is formed between an orthographic projection of the auxiliary electrode on the base substrate and the orthographic projection of the light emitting portion on the base substrate, and the first distance is positively correlated with the thickness of the metal suppression structure.

According to the embodiments of the present disclosure, the display substrate includes a plurality of light emitting devices, the metal suppression layer includes a plurality of metal suppression structures, at least one metal suppression structure corresponds to at least one light emitting device, and different metal suppression structures correspond to different light emitting devices; an orthographic projection of at least one metal suppression structure on the base substrate covers an orthographic projection of the light emitting portion of the light emitting device corresponding to the at least one metal suppression structure on the base substrate; and different metal suppression structures are spaced apart from each other.

According to the embodiments of the present disclosure, the plurality of light emitting devices include a plurality of groups, at least one group includes a plurality of light emitting devices, and at least one metal suppression structure corresponds to at least one group of light emitting devices; and the orthographic projection of at least one metal suppression structure on the base substrate continuously covers an orthographic projection of the light emitting portion of each light emitting device in a group of light emitting devices corresponding to the at least one metal suppression structure on the base substrate.

According to the embodiments of the present disclosure, the plurality of light emitting devices in at least one group of light emitting devices are arranged in a first direction, and two adjacent light emitting devices arranged in the first direction correspond to different light emitting colors.

According to the embodiments of the present disclosure, the plurality of light emitting devices in at least one group of light emitting devices are arranged in an array in a first direction and a second direction, two adjacent light emitting devices arranged in the first direction correspond to different light emitting colors, and two adjacent light emitting devices arranged in the second direction correspond to different light emitting colors.

According to the embodiments of the present disclosure, a second distance is formed between the light emitting portions of two adjacent light emitting devices in a same group of light emitting devices, a third distance is formed between the light emitting portions of two adjacent light emitting devices in adjacent groups of light emitting devices, and the second distance is less than the third distance.

According to the embodiments of the present disclosure, a size of a surface of at least one auxiliary electrode on a side close to the base substrate in a width direction of the at least one auxiliary electrode is less than or equal to the second distance, and the width direction includes a direction from the auxiliary electrode to the light emitting portion adjacent to the auxiliary electrode.

According to the embodiments of the present disclosure, an edge of at least one metal suppression structure overlaps with a first defining portion adjacent to the at least one metal suppression structure in the thickness direction of the display substrate, and an overlapping portion has a first overlapping size; and the first overlapping size is less than or equal to a size of a surface of the auxiliary electrode on a side close to the base substrate in a width direction of the auxiliary electrode.

According to the embodiments of the present disclosure, the display substrate includes a plurality of auxiliary electrodes, at least one auxiliary electrode surrounds at least one metal suppression structure, and two adjacent auxiliary electrodes share a same side edge.

According to the embodiments of the present disclosure, the metal suppression structure contains a metal-exclusive material, and a transmittance of the metal-exclusive material is greater than or equal to a transmittance of the first electrode.

According to a second aspect of the present disclosure, a display panel is provided, including the display substrate as described above.

According to a third aspect of the present disclosure, a display device is provided, including the display panel as described above.

### BRIEF DESCRIPTION OF THE DRAWINGS

The above contents and other objectives, features and advantages of the present disclosure will be more apparent through the following descriptions of the embodiments of the present disclosure with reference to the accompanying drawings. In the accompanying drawings:

FIG. 1 schematically shows a plan view of a display substrate according to the embodiments of the present disclosure;

FIG. 2 schematically shows a first cross-sectional view of a display substrate according to the embodiments of the present disclosure;

FIG. 3 schematically shows a first cross-sectional view of a metal suppression structure according to the embodiments of the present disclosure;

FIG. 4 schematically shows a first cross-sectional view of a metal suppression structure and an auxiliary electrode according to the embodiments of the present disclosure;

FIG. 5 schematically shows a first plan view of a metal suppression structure and an auxiliary electrode according to the embodiments of the present disclosure;

FIG. 6 schematically shows a second cross-sectional view of a metal suppression structure according to the embodiments of the present disclosure;

FIG. 7 schematically shows a second cross-sectional view of a metal suppression structure and an auxiliary electrode according to the embodiments of the present disclosure;

FIG. 8 schematically shows a third cross-sectional view of a metal suppression structure according to the embodiments of the present disclosure;

FIG. 9 schematically shows a third cross-sectional view of a metal suppression structure and an auxiliary electrode according to the embodiments of the present disclosure;

FIG. 10 schematically shows a second plan view of a metal suppression structure and an auxiliary electrode according to the embodiments of the present disclosure;

FIG. 11 schematically shows a first schematic diagram of improving a problem of a large-angle light emission being occluded by an auxiliary electrode according to the embodiments of the present disclosure;

FIG. 12 schematically shows a fourth cross-sectional view of a metal suppression structure according to the embodiments of the present disclosure;

FIG. 13 schematically shows a fourth cross-sectional view of a metal suppression structure and an auxiliary electrode according to the embodiments of the present disclosure;

FIG. 14 schematically shows a third plan view of a metal suppression structure and an auxiliary electrode according to the embodiments of the present disclosure;

FIG. 15 schematically shows a second schematic diagram of improving a problem of a large-angle light emission being occluded by an auxiliary electrode according to the embodiments of the present disclosure;

FIG. 16 schematically shows a cross-sectional view five of a metal suppression structure according to the embodiments of the present disclosure;

FIG. 17 schematically shows a fifth cross-sectional view of a metal suppression structure and an auxiliary electrode according to the embodiments of the present disclosure;

FIG. 18 schematically shows a fourth plan view of a metal suppression structure and an auxiliary electrode according to the embodiments of the present disclosure; and

FIG. 19 schematically shows a plan view of a display panel according to the embodiments of the present disclosure.

### DETAILED DESCRIPTION OF EMBODIMENTS

In order to make objectives, technical solutions and advantages of the embodiments of the present disclosure clearer, technical solutions of the embodiments of the present disclosure will be clearly and completely described below with reference to the accompanying drawings. Obviously, the described embodiments are just some embodiments rather than all embodiments of the present disclosure. Based on the described embodiments of the present disclosure, all additional embodiments obtained by those ordinary skilled in the art without carrying out inventive effort fall within the scope of protection of the present disclosure.

It should be noted that in the accompanying drawings, for clarity and/or description purposes, a size and relative size of an element may be enlarged. Accordingly, the size and relative size of each element are not necessarily limited to those shown in the figures. In the specification and the accompanying drawings, the same or similar reference numerals represent the same or similar components.

When an element is described as being “on”, “connected to” or “coupled to” another element, the element may be directly on the another element, directly connected to the another element, or directly coupled to the another element, or an intermediate element may be provided. However, when an element is described as being “directly on”, “directly connected to” or “directly coupled to” another element, no intermediate element is provided. Other terms and/or expressions used to describe a relationship between elements, such as “between” and “directly between”, “adjacent to” and “directly adjacent to”, “on” and “directly on”, and so on, should be interpreted in a similar manner. Moreover, the term “connection” may refer to a physical connection, an electrical connection, a communicative connection, and/or a fluid connection. In addition, X-axis, Y-axis and Z-axis are not limited to three axes of a rectangular coordinate system, and may be interpreted in a broader meaning. For example, the X-axis, the Y-axis and the Z-axis may be perpendicular to each other, or may represent different directions that are not perpendicular to each other. For objectives of the present disclosure, “at least one of X, Y or Z” and “at least one selected from a group consisting of X, Y and Z” may be interpreted as only X, only Y, only Z, or any combination of two or more of X, Y and Z, such as XYZ, XYY, YZ and ZZ. As used herein, the term “and/or” includes any and all combinations of one or more of the listed related items.

It should be noted that although the terms “first”, “second”, etc. may be used herein to describe various components, members, elements, regions, layers and/or portions, these components, members, elements, regions, layers and/or portions should not be limited by these terms. Rather, these terms are used to distinguish one component, member, element, region, layer and/or portion from another one. Thus, for example, a first component, a first member, a first element, a first region, a first layer and/or a first portion discussed below may be referred to as a second component, a second member, a second element, a second region, a second layer and/or a second portion without departing from teachings of the present disclosure.

For ease of description, spatial relationship terms, such as “upper”, “lower”, “left”, “right”, etc. may be used herein to describe a relationship between an element or feature and another element or feature as shown in the figures. It should be understood that the spatial relationship terms are intended to cover other different orientations of a device in use or operation in addition to the orientation described in the figures. For example, if a device in the figures is turned upside down, an element or feature described as “below” or “under” another element or feature will be oriented “above” or “on” the another element or feature.

Here, the terms “substantially”, “about”, “approximately” and other similar terms are used as terms of approximation rather than terms of degree, and they are intended to explain an inherent deviation of a measured or calculated value that will be recognized by those ordinary skilled in the art. Taking into account a process fluctuation, a measurement problem, an error related to a measurement of a specific quantity (that is, a limitation of a measurement system) and other factors, the terms “substantially”, “about” or “approximately” used herein includes a stated value and means that a specific value determined by those ordinary skilled in the art is within an acceptable range of deviation. For example, “about” may mean being within one or more standard deviations, or within ±30%, ±20%, ±10% or ±5% of the stated value.

It should be noted that the expression “the same layer” herein refers to a layer structure that is formed by firstly forming, using a same film forming process, a film layer used to form a specific pattern, and then patterning, using one-time patterning process, the film layer with a same mask. Depending on different specific patterns, the one-time patterning process may include a plurality of exposure, development or etching processes, and the specific pattern in the formed layer structure may be continuous or discontinuous. That is, a plurality of elements, components, structures and/or portions located in the “same layer” are made of the same material and formed by the same patterning process. Generally, a plurality of elements, components, structures and/or portions located in the “same layer” have substantially the same thickness.

Those skilled in the art should understand that, unless otherwise specified, the expression “height” or “thickness” herein refers to a size in a direction perpendicular to a surface of each film layer provided on the display substrate, that is, a size in a light emitting direction of the display substrate, or called a size in a normal direction of the display device.

In an example, a display substrate is provided. The display substrate in this example includes a base substrate and a plurality of light emitting devices provided on the base substrate. The light emitting device may include a first electrode, a second electrode, and a light emitting portion located between the first electrode and the second electrode. One of the first electrode and the second electrode is an anode, and the other is a cathode. For example, the light emitting device may be a top-emitting light emitting device. The first electrode, the light emitting portion and the second electrode are sequentially arranged in a direction away from the base substrate, where the first electrode is the anode and the second electrode is the cathode. In this example, the cathode of the top-emitting light emitting device is made of a metal or alloy having a low work function. In order to achieve a high transmittance, the cathode has a small thickness, and specifically, the thickness of the cathode is reduced to less than 20 nm. Due to the small thickness of the cathode, the cathode has a large resistance, and a significant voltage drop may be generated. In a case of a large-sized display substrate such as a display substrate larger than 10 inches, it is possible to generate a significant difference in brightness.

In view of this, the embodiments of the present disclosure provide a display substrate, including: a base substrate, a light emitting functional layer provided on the base substrate, a first electrode layer provided on a side of the light emitting functional layer away from the base substrate, a metal suppression layer provided on a side of the first electrode layer away from the base substrate, an auxiliary electrode layer provided on a side of the first electrode layer away from the base substrate, and a light emitting device provided on the base substrate. The light emitting device includes a light emitting portion and a first electrode, and the first electrode is located in the first electrode layer. The metal suppression layer includes a metal suppression structure, and an orthographic projection of the light emitting portion on the base substrate is located within an orthographic projection of the metal suppression structure on the base substrate. The auxiliary electrode layer includes an auxiliary electrode, which is electrically connected to the first electrode and spaced apart from the metal suppression structure.

In the embodiments of the present disclosure, the metal suppression structure contains a metal-exclusive material, which is exclusive from, when forming an auxiliary electrode by an evaporation process, a metal material used to form the auxiliary electrode. Therefore, the auxiliary electrode may be formed to avoid a region where the metal suppression structure is located, that is, a finally formed auxiliary electrode is spaced apart from the metal suppression structure, so that the auxiliary electrode is limited outside (or slightly overlaps with an edge of) a range defined by the metal suppression structure. In the embodiments of the present disclosure, an orthographic projection of the light emitting portion on the base substrate is located within an orthographic projection of the metal suppression structure on the base substrate, so that the formed auxiliary electrode may avoid the light emitting portion and may be prevented from occluding light emitted from the light emitting portion. Moreover, the formed auxiliary electrode is electrically connected to the first electrode, so that a resistance on the first electrode may be reduced, then a voltage drop problem on the first electrode may be improved, and a brightness uniformity of a large-sized display substrate using a top-emitting light emitting device may be improved.

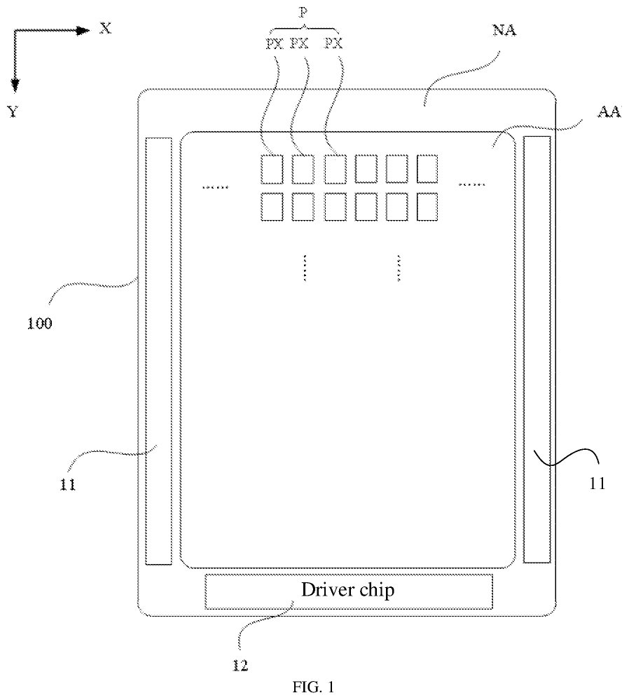

The display substrate of the embodiments of the present disclosure will be described in detail below with reference to FIG. 1 to FIG. 18. It should be noted that the accompanying drawings in the embodiments of the present disclosure just illustrate positions of various film layers, and sizes of the film layers in the drawings do not represent true values. For example, the auxiliary electrode and the metal suppression structure may have a thickness in the nanometer level and a horizontal size in the micrometer level. In order to clearly show a plurality of structures in a figure, the embodiments of the present disclosure exaggerate the thickness of the auxiliary electrode and the thickness of the metal suppression structure in the figure, and specific sizes of the two depend on a textual portion recorded in the specification.

The embodiments of the present disclosure provide a display substrate, and FIG. 1 schematically shows a plan view of the display substrate according to the embodiments of the present disclosure. Referring to FIG. 1, the display substrate of the embodiments of the present disclosure includes a display region AA and a peripheral region NA located on at least one side of the display region AA.

The display region AA may have various shapes. For example, the display region AA may be provided in various shapes such as a closed polygon including straight sides (e.g., a rectangle), a circle, an ellipse, etc. that includes a curved side, and a semicircle, a semi-ellipse, etc. that includes a straight side and a curved side. In the embodiments of the present disclosure, the display region AA is provided as a region having a quadrangular shape including straight sides. It should be understood that this is just an exemplary embodiment of the present disclosure, rather than a limitation to the present disclosure.

The peripheral region NA may be arranged on at least one side of the display region AA. In the embodiments of the present disclosure, the peripheral region NA may surround a periphery of the display region AA. In the embodiments of the present disclosure, the peripheral region NA may include a transverse portion extending in the first direction X and a longitudinal portion extending in the second direction Y.

The display substrate may further include a gate driving circuit 11 and a driver chip 12, which are located in the peripheral region NA. For example, the gate driving circuit 11 may be located on at least one side of the display region AA. In the embodiments shown in FIG. 1, the gate driving circuit 11 is located on a left side and a right side of the display region AA, respectively. It should be noted that the left side and the right side may refer to a left side and a right side of the display substrate (screen) viewed by human eyes during display. For example, the driver chip 12 may be located on at least one side of the display region AA. In the embodiments shown in FIG. 1, the driver chip 12 is located on a lower side of the display region AA. It should be noted that the lower side may be a lower side of the display substrate (screen) viewed by human eyes during display.

The driver chip 12 includes a data driving circuit, which is used to sequentially latch input data in a timing manner according to clock signals and convert the latched data into analog signals, and then input the analog signals to data lines on the display substrate. The gate driving circuit 11 is generally implemented by a shift register, which converts the clock signals into on/off voltages and outputs the on/off voltages to gate lines on the display substrate.

It should be noted that FIG. 1 shows that the gate driving circuit 11 is located on the left side and the right side of the display region AA, and the driver chip 12 is located on the lower side of the display region AA. However, the embodiments of the present disclosure are not limited thereto. The gate driving circuit 11 and the driver chip 12 may be located at any suitable position in the peripheral region NA.

For example, a GOA technology, namely Gate Driver on Array, may be adopted for the gate driving circuit 11. In the GOA technology, the gate driving circuit 11 is provided directly on an array substrate to replace an external chip. Each GOA unit serves as a stage of shift register, and each stage of shift register is connected to a gate line. Scanning signals are sequentially output through stages of shift registers to achieve progressive scanning of pixel units. In some embodiments, each stage of shift register may also be connected to a plurality of gate lines. In this way, it may adapt to a development trend of high resolution and narrow bezel of display substrates. The driver chip 12 may be folded to a back side of the display substrate through a structure such as chip on film.

FIG. 2 schematically shows a first cross-sectional view of a display substrate according to the embodiments of the present disclosure.

Referring to FIG. 1 and FIG. 2, the display substrate may include a base substrate 100, and a plurality of pixel units P provided on the base substrate 100 and located in the display region AA. Each pixel unit P may include a plurality of sub-pixels PX, such as a first sub-pixel, a second sub-pixel, and a third sub-pixel. For the sake of understanding, the first sub-pixel, the second sub-pixel and the third sub-pixel may be described as a red sub-pixel Pr, a green sub-pixel Pg, and a blue sub-pixel Pb, respectively. However, the embodiments of the present disclosures are not limited to this.

For example, each pixel unit P may include a plurality of sub-pixels PX, such as a first sub-pixel, a second sub-pixel, and a third sub-pixel. The pixel unit may be divided into a first pixel unit and a second pixel unit. The first sub-pixel and the second sub-pixel of the first pixel unit are described as a red sub-pixel Pr and a green sub-pixel Pg, respectively. The first sub-pixel and the second sub-pixel of the second pixel unit are described as a blue sub-pixel Pb and a green sub-pixel Pg, respectively. The third sub-pixels of the two pixel units are borrowed from each other. For example, the third sub-pixel of the first pixel unit may be described as a blue sub-pixel Pb borrowed from the second pixel unit, and the third sub-pixel of the second pixel unit may be described as a red sub-pixel Pr borrowed from the first pixel unit. In such embodiments, the red sub-pixel Pr and the blue sub-pixel Pb are located in different rows. A part of the green sub-pixels Pg on the display substrate is located in the same row as the red sub-pixel Pr, and the red sub-pixel Pr and the green sub-pixel Pg are alternately arranged in a row direction. The other part of the green sub-pixels Pg on the display substrate is located in the same row as the blue sub-pixel Pb, and the blue sub-pixel Pb and the green sub-pixel Pg are alternately arranged in the row direction.

Each sub-pixel PX may include a light emitting device L and a pixel circuit for driving the light emitting device L. For example, the red sub-pixel Pr may include a first light emitting device and a first pixel circuit for driving the first light emitting device, and the first light emitting device may emit red light; the green sub-pixel Pg may include a second light emitting device and a second pixel circuit for driving the second light emitting device, and the second light emitting device may emit green light; the blue sub-pixel Pb may include a third light emitting device and a third pixel circuit for driving the third light emitting device, and the third light emitting device may emit blue light.

In some specific embodiments, the display substrate further includes a light emitting functional layer E provided on the base substrate 100 and a first electrode layer 110 provided on a side of the light emitting functional layer E away from the base substrate 100.

In the embodiments of the present disclosures, the light emitting device L may be an organic light emitting diode (OLED) or a quantum-dot light emitting diode (QLED), both of which are active light emitting devices having advantages of self-luminescence, wide viewing angle, high contrast, low power consumption, very fast reaction, lightweight, bendability, and low costs, etc. For clarity, unless otherwise specified, the light emitting device L being an organic light emitting diode is illustrated below by way of example in describing the display substrate of the embodiments of the present disclosure.

Exemplarily, the display substrate further includes a second electrode layer 120 located between the light emitting functional layer E and the base substrate 100. The light emitting device L includes a light emitting portion E1, a first electrode 111 located in the first electrode layer 110, and a second electrode 121 located in the second electrode layer 120. One of the second electrode 121 and the first electrode 111 is an anode, and the other is a cathode. For example, the light emitting device L is a top-emitting light emitting device, the first electrode 111 is the cathode, and the second electrode 121 is the anode. The first electrode 111 of the light emitting device L is made of a metal or alloy having a low work function. In order to achieve a high transmittance, the cathode 111 has a small thickness, and specifically, the thickness of the cathode 111 is reduced to less than 20 nm. The light emitting functional layer E includes a pixel defining layer 150, the pixel defining layer 150 includes a pixel opening 151, and a luminescent material may be formed in the pixel opening 151. In the embodiments of the present disclosure, the luminescent material may be formed in the pixel opening 151 using a fine metal mask (FMM) through an evaporation process. In addition to being located in the pixel opening 151, the luminescent material may further cover a side wall of the pixel opening 151 or even cover a surface of the pixel defining layer 151 on a side away from the base substrate 100. The light emitting portion E1 in the embodiments of the present disclosure may refer to a portion of the luminescent material located in the pixel opening 151, as shown in FIG. 2. In other words, the light emitting portion E1 in the embodiments of the present disclosure may refer to a portion of the luminescent material located in a valid light emitting region.

The pixel circuit includes a plurality of transistors, for example, the pixel circuit includes an input transistor, a driving transistor, a reset transistor, a light emission control transistor, and a storage capacitor, etc. The second electrode 121 may be electrically connected to the driving transistor, so as to transmit a driving current provided by the driving transistor to the light emitting portion E1.

The light emitting portion E1 includes a hole injection layer, a hole transport layer, a light emitting layer, an electron transport layer, and an electron injection layer sequentially stacked in a direction away from the base substrate 100. The first electrode 111 is electrically connected to a power line that may provide a constant low-level signal, so that the light emitting portion E1 may emit light in response to an electrical signal loaded on the first electrode 111 and the second electrode 121, thereby achieving a display function.

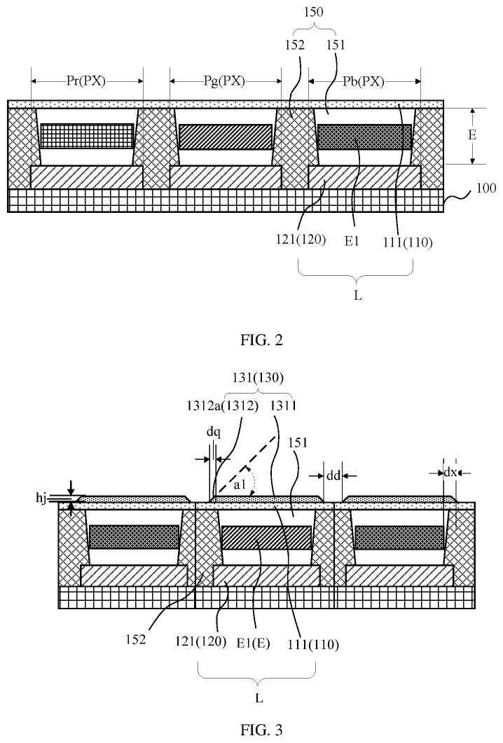

FIG. 3 schematically shows a first cross-sectional view of a metal suppression structure according to the embodiments of the present disclosure, and FIG. 4 schematically shows a first cross-sectional view of a metal suppression structure and an auxiliary electrode according to the embodiments of the present disclosure.

Referring to FIG. 3 and FIG. 4, in the embodiments of the present disclosure, the display substrate further includes a metal suppression layer 130 provided on a side of the first electrode layer 110 away from the base substrate 100, and an auxiliary electrode layer 140 provided on the side of the first electrode layer 110 away from the base substrate 100. The metal suppression layer 130 includes a metal suppression structure 131, and the auxiliary electrode layer 140 includes an auxiliary electrode 141.

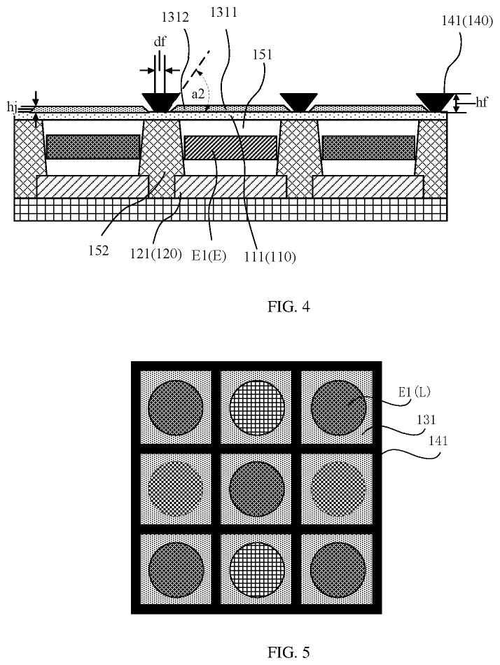

FIG. 5 schematically shows a first plan view of the metal suppression structure and the auxiliary electrode according to the embodiments of the present disclosure.

Referring to FIG. 5, in the embodiments of the present disclosure, the display substrate may be provided with a plurality of light emitting devices L, and also provided with a plurality of metal suppression structures 131 and a plurality of auxiliary electrodes 141. The plurality of metal suppression structures 131 may be spaced apart from each other, and the auxiliary electrode 141 may be arranged on a periphery of the metal suppression structure 131. The auxiliary electrode 141 may be a continuous structure or a plurality of block structures, which may be determined according to actual needs and not limited here. For example, the auxiliary electrode 141 may be a continuous ring structure, and adjacent auxiliary electrodes 141 may be connected and formed as an integrated structure.

A light emitting device L may be provided with a metal suppression structure 131 and a corresponding auxiliary electrode 141, or a plurality of light emitting devices L may be provided with a metal suppression structure 131 and a corresponding auxiliary electrode 141, which will be described in detail below and not be elaborated here. For clarity, unless otherwise specified, one light emitting device L and the metal suppression structure 131 and auxiliary electrodes 141 corresponding to that light emitting device L are illustrated by way of example in describing the display substrate of the embodiments of the present disclosure.

The metal suppression structure 131 may contain a metal-exclusive material, which may refer to a material that is mutually exclusive from and not bonded to a metal material during a vacuum evaporation process. The metal-exclusive material may be an organic small molecule compound or an inorganic compound. For example, the metal suppression structure 131 may contain amine, diamine, and triamine materials.

In the embodiments of the present disclosure, when forming the auxiliary electrode 141 on the first electrode 111 by the evaporation process, by using the metal suppression structure 131, the auxiliary electrode 141 may avoid a region where the metal suppression structure 131 is located, that is, the finally formed auxiliary electrode 141 may be spaced apart from the metal suppression structure 131, so that the auxiliary electrode 141 is limited outside (or slightly overlaps with an edge of) a range defined by the metal suppression structure 131.

In the embodiments of the present disclosure, an orthographic projection of the light emitting portion E1 on the base substrate 100 is located within an orthographic projection of the metal suppression structure 131 on the base substrate 100. Therefore, the formed auxiliary electrode 141 may avoid the light emitting portion E1 and may be prevented from affecting a light emission of the light emitting portion E1, so that a design of the auxiliary electrode 141 may be more flexible. For example, since the auxiliary electrode 141 may avoid the light emitting portion E1, it does not need to consider the transmittance of the auxiliary electrode 141, then the auxiliary electrode 141 may have a large thickness or may be made of a metal or alloy material having a lower resistivity, so that the resistance on the first electrode 141 may be reduced well, or a space occupation of the auxiliary electrode 141 may be reduced on the basis of achieving a good resistance reduction.

In the embodiments of the present disclosure, the metal suppression structure 131 is made of a metal-exclusive material, which has a transmittance similar to that of a highly transparent material such as glass. Therefore, an influence of the metal suppression structure 131 on the light emission of the light emitting portion E1 may be almost negligible. Moreover, the metal suppression structure 131 does not involve a consideration of conductivity, and may be designed to have a small thickness (e.g., close to the thickness of the first electrode 111), so as to avoid an influence on a film thickness of the display substrate.

Moreover, the formed auxiliary electrode 141 is electrically connected to the first electrode 111, so that the resistance on the first electrode 111 may be reduced, a voltage drop problem on the first electrode 111 may be improved, and a brightness uniformity of a large-sized display substrate using a top-emitting light emitting device may be improved.

The display substrate in some exemplary embodiments of the present disclosure will be further described below with reference to FIG. 1 to FIG. 18.

Referring to FIG. 2 to FIG. 5, in some specific embodiments, the light emitting functional layer E includes a pixel defining layer 150. The pixel defining layer 150 includes a pixel opening 151 and a first defining portion 152 surrounding the pixel opening 151, and the light emitting portion E1 of the light emitting device L is located in the pixel opening 151. The auxiliary electrode 141 at least partially surrounds the metal suppression structure 131. An orthographic projection of the auxiliary electrode 141 on the base substrate 100 is located within an orthographic projection of the first defining portion 152 on the base substrate 100.

In the embodiments of the present disclosure, the pixel defining layer 150 covers a side of the second electrode 121 away from the base substrate 100, and the pixel opening 151 exposes a part of the second electrode layer 120. Specifically, at a position corresponding to the light emitting device L, the second electrode 121 of the light emitting device L located in the second electrode layer 120 is exposed, so that the light emitting portion E1 formed in the pixel opening 151 may be electrically connected to the exposed second electrode 121.

A first electrode layer 110 is formed on a side of the pixel defining layer 150 away from the base substrate 100. The first electrode 111 of the light emitting device L located in the first electrode layer 110 covers the pixel opening 151 and is electrically connected to the light emitting portion E1 in the pixel opening 151. Then, the first electrode 111 and the second electrode 121 may provide corresponding driving signals to the light emitting portion E1 to drive the light emitting portion E1 to emit light. For example, the first electrode 111 is electrically connected to a power line used to provide a constant low-level voltage signal, and the second electrode 121 is electrically connected to the driving transistor in the pixel circuit. The light emitting portion E1 may emit light with corresponding brightness according to a magnitude of the driving current provided by the driving transistor.

The metal suppression structure 131 covers the first electrode layer 110, specifically on a light exit side of the light emitting portion E1 of the light emitting device L. Both the metal suppression structure 131 and the first electrode 111 have good transmittance. For example, the transmittance of the metal suppression structure 131 is greater than or equal to that of the first electrode 111.

The auxiliary electrode 141 may continuously surround the metal suppression structure 131 or non-continuously surround the metal suppression structure. For example, the auxiliary electrode 141 may be a continuous ring structure, or the auxiliary electrode 141 may be a structure enclosed by a plurality of discontinuous strips. Optionally, the orthographic projection of the metal suppression structure 131 on the base substrate 100 not only covers the orthographic projection of the light emitting portion E1 of the light emitting device L on the base substrate 100, but also appropriately extends outward to reduce a region used for forming the auxiliary electrode 141 and limit the size of the auxiliary electrode 141, so that the orthographic projection of the auxiliary electrode 141 on the base substrate 100 does not overlap with the orthographic projection of the light emitting portion E1 of the light emitting device L on the base substrate 100, then the auxiliary electrode 141 may be prevented from occluding the light emitting portion E1.

In some specific embodiments, the metal suppression structure 131 includes a first middle portion 1311 and a first edge portion 1312 surrounding the first middle portion 1311. The first edge portion 1312 overlaps with the first defining portion 152 in a thickness direction of the display substrate. A thickness hf of the auxiliary electrode 141 is greater than or equal to a thickness hj of the metal suppression structure 131. The auxiliary electrode 141 overlaps at least partially with the first edge portion 1312 in the thickness direction of display substrate.

Exemplarily, the metal suppression structure 131 may be directly opposite to the pixel opening 151. For example, a center of the metal suppression structure 131 may coincide with a center of the pixel opening 151. The metal suppression structure 131 may extend outward from the center until extending outside the pixel opening 151 and overlapping with the first edge portion 1312 in the thickness direction of the display substrate, then the metal suppression structure 131 may completely cover the light emitting portion E1 in the pixel opening 151 to ensure that no auxiliary electrode 141 is located above the light emitting portion E1.

In the embodiments of the present disclosure, a morphology of the metal suppression structure 131 has a direct influence on a morphology of the auxiliary electrode 141. Specifically, it is possible to adjust the morphology of the auxiliary electrode 141 by controlling the thickness hj of the metal suppression structure 131. In some specific embodiments, the thickness hf of the auxiliary electrode 141 is negatively correlated with the thickness hj of the metal suppression structure 131. A first distance w1 is formed between the orthographic projection of the auxiliary electrode 141 on the base substrate 100 and the orthographic projection of the light emitting portion E1 on the base substrate 100, and the first distance w1 is positively correlated with the thickness hj of the metal suppression structure 131. For example, the greater the thickness hj of the metal suppression structure 131, the less the thickness hf of the auxiliary electrode 141. The auxiliary electrode 141 formed by the evaporation process has a small area on a side close to the base substrate 100 and a large area on a side away from the base substrate 100. For example, a cross section of the auxiliary electrode 141 in a width direction of the auxiliary electrode 141 may be an inverted trapezoid. The less the thickness hf of the auxiliary electrode 141, the less the size of the auxiliary electrode 141 in the width direction, that is, the greater the first distance w1.

Therefore, it is possible to control the distance between the auxiliary electrode 141 and the light emitting portion E1 by setting the thickness hj of the metal suppression structure 131, so as to limit the auxiliary electrode 141 outside the pixel opening 151. For example, the orthographic projection of the auxiliary electrode 141 on the base substrate 100 is located within the orthographic projection of the first defining portion 152 on the base substrate 100, so that the auxiliary electrode 141 may be prevented from occluding the light emitting portion E1.

In the embodiments of the present disclosure, the morphology of the auxiliary electrode 141 is controlled by adjusting the thickness hj of the metal suppression structure 131. Accordingly, when forming different sizes of auxiliary electrodes 141, there is no need to change an opening size of a mask used to prepare the metal suppression structure 131, and it is possible to control the morphology and size of the auxiliary electrode 141 by only adjusting a preparation time and feeding amount of the metal suppression structure 131, which has advantages of convenient process, low costs, flexibility and easy adjustment.

Referring to FIG. 4, in some specific embodiments, the thickness hj of the metal suppression structure 131 may be set small, and the thickness hf of the auxiliary electrode 141 may be set large. Accordingly, the auxiliary electrode 141 may have a large volume without occluding the light emitting portion E1, so that the resistance on the first electrode 111 may be significantly reduced, the voltage drop problem may be improved, and the display uniformity may be improved. For example, a ratio of the thickness hf of the auxiliary electrode 141 to the thickness hj of the metal suppression structure 131 may be set to 1:1 to 100:1. For example, the thickness hf of the auxiliary electrode 141 may be set to 50 nm to 200 nm, and the thickness hj of the metal suppression structure 131 may be set to 2 nm to 50 nm.

Referring to FIG. 3 and FIG. 4, in some specific embodiments, the first edge portion 1312 includes a first inclined portion 1312a. A first angle a1 is formed between a surface of the first inclined portion 1312a on a side away from the base substrate 100 and the first electrode 111, and a second angle a2 is formed between a surface adjacent to the first inclined portion 1312a of the auxiliary electrode 141 and the first electrode 111. The first angle a1 is substantially the same as the second angle a2.

In the embodiments of the present disclosure, the first angle a1 specifically refers to an acute angle between an inclined surface of the first inclined portion 1312a and the first electrode 111, the second angle a2 specifically refers to an acute angle between an inclined surface of the auxiliary electrode 141 and the first electrode 111, and the two angles are substantially the same. For example, the first angle a1 may be set to 2° to 30°, and the second angle a2 may be set to 1° to 30°. For example, a lower limit of the first angle a1 is set to be greater than a lower limit of the second angle a2, which may overcome a limitation of a preparation process and ensure that the second angle a2 may reach 1°.

In the embodiments of the present disclosure, the first angle a1 is substantially the same as the second angle a2, that is, the first inclined portion 1312a is substantially parallel to the inclined surface of the auxiliary electrode 141. For example, it is possible to control the evaporation time and feeding amount to obtain an appropriate thickness hf of the auxiliary electrode 141 (not exceeding an expected thickness), so that the first inclined portion 1312a may be parallel to the inclined surface of the auxiliary electrode 141.

In some specific embodiments, a cross-sectional shape of the metal suppression structure 131 in a direction perpendicular to the base substrate 100 includes a trapezoid or an inverted trapezoid. For example, the cross-sectional shape of the metal suppression structure 131 in the direction perpendicular to the base substrate 100 is a trapezoid, so that an opening that has a width gradually decreasing in a direction close to the base substrate 100 may be formed between adjacent metal suppression structures 131, which may help form an auxiliary electrode 141 with a narrow bottom and a wide top through the evaporation process in a gap between adjacent metal suppression structures 131 (for example, referring to FIG. 4, the cross-sectional shape of the auxiliary electrode 141 in the direction perpendicular to the base substrate 100 is an inverted trapezoid).

Exemplarily, in a direction from the edge of the metal suppression structure 131 to the center of the metal suppression structure 131, a size dq of the first inclined portion 1312a may be set to 0.1 μm to 2 μm.

In other specific embodiments, it is also possible to reduce the volume of the auxiliary electrode 141 by adjusting the thickness hj of the metal suppression structure 131, so as to improve a problem of a large-angle light ray (such as exceeding 45°) of the light emitting portion E1 being occluded by the auxiliary electrode 141.

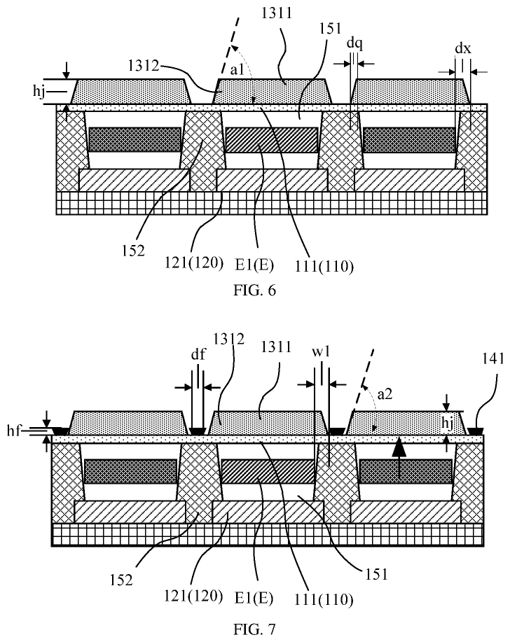

FIG. 6 schematically shows a second cross-sectional view of the metal suppression structure according to the embodiments of the present disclosure, and FIG. 7 schematically shows a second cross-sectional view of the metal suppression structure and the auxiliary electrode according to the embodiments of the present disclosure.

Referring to FIG. 6 and FIG. 7, in some specific embodiments, the metal suppression structure 131 includes a first middle portion 1311 and a first edge portion 1312 surrounding the first middle portion 1311. The first edge portion 1312 overlaps with the first defining portion 152 in the thickness direction of the display substrate. The thickness hf of the auxiliary electrode 141 is less than the thickness hj of the metal suppression structure 131. The auxiliary electrode 141 is spaced apart from the first edge portion 1312 in the thickness direction of the display substrate.

In the embodiments of the present disclosure, it is possible to reduce the thickness hf of the auxiliary electrode 141 by increasing the thickness hj of the metal suppression structure 131. Referring to FIG. 7, the cross section of the auxiliary electrode 141 is an inverted trapezoid, and a decrease in the thickness of the auxiliary electrode 141 may reduce a space occupation of the auxiliary electrode 141 in a horizontal direction, so that the auxiliary electrode 141 does not overlap with the first edge portion 1312 in the thickness direction of the display substrate. Compared to the aforementioned embodiments, such embodiments may be implemented to reduce the volume of the auxiliary electrode 141, so that the occlusion of the large-angle light ray of the light emitting portion E1 by the auxiliary electrode 141 may be improved.

In some specific embodiments, a ratio of the thickness hf of the auxiliary electrode 141 to the thickness hj of the metal suppression structure 131 is set to 1:20 to 2:5. For example, the thickness hf of the auxiliary electrode 141 may be set to 5 nm to 20 nm, and the thickness hj of the metal suppression structure 131 may be set to 50 nm to 100 nm.

In the embodiments of the present disclosure, the first angle a1 may be set to 5° to 30°, and the second angle a2 may be set to 5° to 30°.

Exemplarily, a size of the surface of the auxiliary electrode 141 on the side close to the base substrate 100 in the first direction X may be set to 1 μm to 15 μm, and a size of the surface of the auxiliary electrode 141 on the side away from the base substrate 100 in the first direction X may be controlled by adjusting the thickness hf of the auxiliary electrode 141 and the size of the second angle a2.

In some specific embodiments, the edge of at least one metal suppression structure 131 overlaps with a first defining portion 152 adjacent to the metal suppression structure in the thickness direction of the display substrate, and an overlapping portion has a first overlapping size dx. The first overlapping size dx is less than or equal to a size df of the surface of the auxiliary electrode 141 on the side close to the base substrate 100 in the width direction of the auxiliary electrode 141. For example, the first overlapping size dx is set to 1 μm to 10 μm. In the embodiments of the present disclosure, the auxiliary electrode 141 may be a strip, and the width direction of the auxiliary electrode 141 may be perpendicular to an extension direction of the auxiliary electrode 141. For example, the size df of the auxiliary electrode 141 in the width direction may be set to 1 to 15 μm.

For example, in the direction from the edge of the metal suppression structure 131 to the center of the metal suppression structure 131, the size dq of the first inclined portion 1312a is less than or equal to the first overlapping size dx. For example, in the embodiments of the present disclosure, the first overlapping size dx is set to 1 μm to 10 μm, and the size of the first inclined portion 1312a may be set to 3 μm to 10 μm.

In some specific embodiments, the display substrate includes a plurality of light emitting devices L, and the metal suppression layer 130 includes a plurality of metal suppression structures 131. At least one metal suppression structure 131 corresponds to at least one light emitting device L, and different metal suppression structures 131 correspond to different light emitting devices L. An orthographic projection of at least one metal suppression structure 131 on the base substrate 100 covers an orthographic projection of the light emitting portion E1 of the corresponding light emitting device L on the base substrate 100. Different metal suppression structures 131 are spaced apart from each other.

In the embodiments of the present disclosure, the plurality of light emitting devices L may be arranged in an array in the first direction X and the second direction Y. However, the embodiments of the present disclosure is not limited to this. For example, the plurality of light emitting devices L may also be arranged in an array in directions inclined with the first direction X and the second direction Y.

Referring to FIG. 4 and FIG. 5, in the embodiments of the present disclosure, each light emitting device L may be provided with a corresponding metal suppression structure 131. When each light emitting device L is provided with a corresponding metal suppression structure 131, an auxiliary electrode 141 may surround a periphery of that light emitting device L, so that the auxiliary electrode 141 may have a large area.

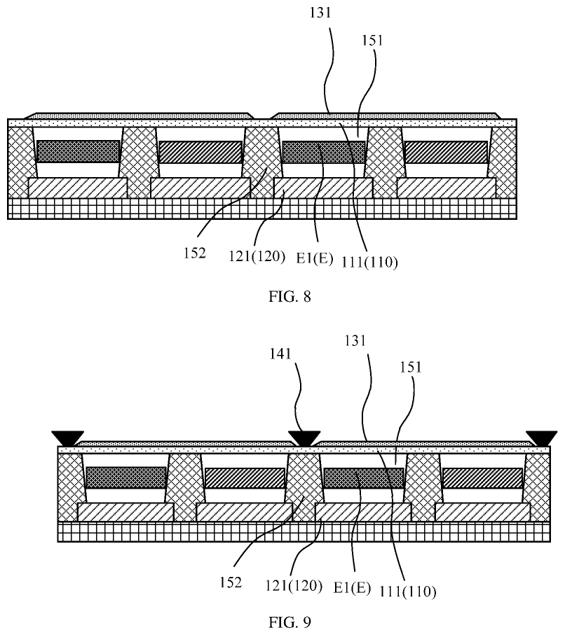

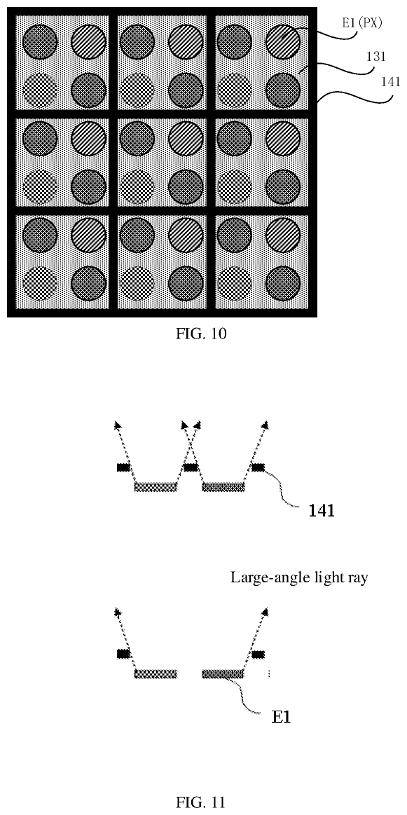

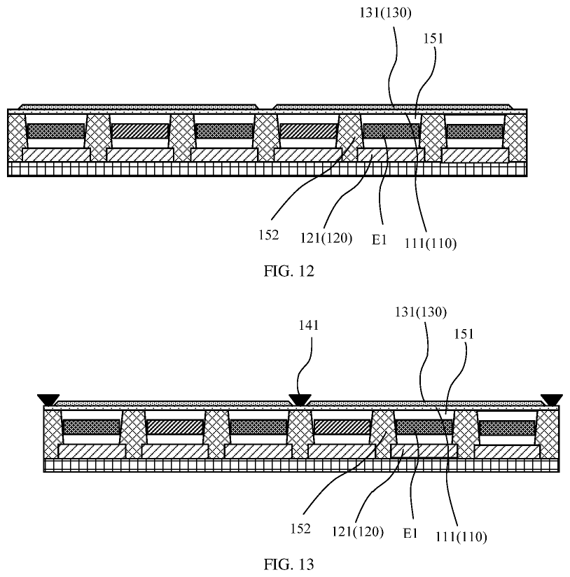

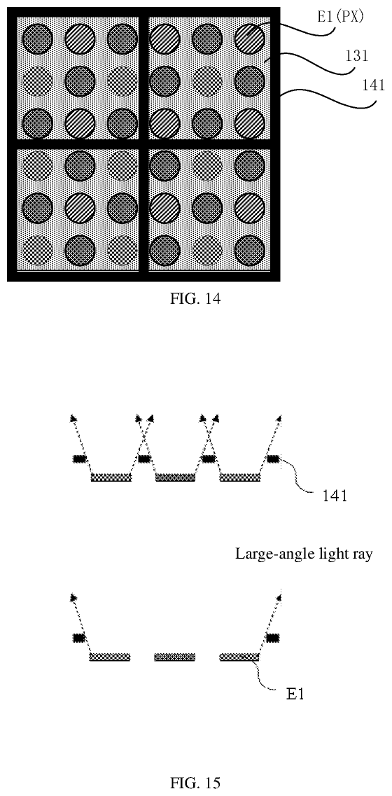

FIG. 8 schematically shows a third cross-sectional view of a metal suppression structure according to the embodiments of the present disclosure, FIG. 9 schematically shows a third cross-sectional view of a metal suppression structure and an auxiliary electrode according to the embodiments of the present disclosure, FIG. 10 schematically shows a second plan view of a metal suppression structure and an auxiliary electrode according to the embodiments of the present disclosure, FIG. 11 schematically shows a first schematic diagram of improving a problem of a large-angle light emission being occluded by an auxiliary electrode according to the embodiments of the present disclosure, FIG. 12 schematically shows a fourth cross-sectional view of a metal suppression structure according to the embodiments of the present disclosure, FIG. 13 schematically shows a fourth cross-sectional view of a metal suppression structure and an auxiliary electrode according to the embodiments of the present disclosure, FIG. 14 schematically shows a third plan view of a metal suppression structure and an auxiliary electrode according to the embodiments of the present disclosure, and FIG. 15 schematically shows a second schematic diagram of improving a problem of a large-angle light emission being occluded by an auxiliary electrode according to the embodiments of the present disclosure.

Referring to FIG. 8 to FIG. 15, in some specific embodiments, a plurality of light emitting devices L may be provided with one corresponding metal suppression structure 131. For example, in some specific embodiments, the plurality of light emitting devices L include a plurality of groups, at least one group includes a plurality of light emitting devices L, and at least one metal suppression structure 131 corresponding to at least one group of light emitting devices L. An orthographic projection of at least one metal suppression structure 131 on the base substrate 100 continuously covers an orthographic projection of the light emitting portion E1 of each light emitting device L in the corresponding group of light emitting devices L on the base substrate 100.

In the embodiments of the present disclosure, when a plurality of light emitting devices L is provided with one metal suppression structure 131, the metal suppression structure 131 may continuously cover between adjacent light emitting devices L, so that no auxiliary electrode 141 is formed between the two light emitting devices L. Compared to the aforementioned embodiments, such embodiments may be implemented to reduce the area of the auxiliary electrode 141, which may help further improve the problem of a large-angle light ray of the light emitting portion E1 being occluded by the auxiliary electrode 141.

The metal suppression structure 131 continuously covers a group of light emitting devices L, and the auxiliary electrode 141 is located outside the metal suppression structure 131, that is, outside a region where the group of light emitting devices L is located. Referring to FIG. 11 and FIG. 15, no auxiliary electrode 141 is formed between two adjacent light emitting devices L in a same group. Therefore, no auxiliary electrode 141 may occlude a large-angle light ray between the two light emitting devices L.

In some specific embodiments, the plurality of light emitting devices L in at least one group of light emitting devices L are arranged in the first direction X, or the plurality of light emitting devices L in at least one group of light emitting devices L are arranged in an array in the first direction X and the second direction Y. In other words, in the embodiments of the present disclosure, a metal suppression structure 131 may be provided for a plurality of light emitting devices L adjacent in the first direction X, or a metal suppression structure 131 may be provided for a plurality of light emitting devices L adjacent in the first direction X and the second direction Y.

When a group of light emitting devices L includes light emitting devices L arranged in the first direction X, a large-angle light ray between two light emitting devices L adjacent in the first direction may not be occluded by the auxiliary electrode 141.

When a group of light emitting devices L includes light emitting devices L arranged in an array in the first direction X and the second direction Y, a large-angle light ray between two light emitting devices L adjacent in the first direction X and a large-angle light ray between two light emitting devices L adjacent in the second direction Y may not be occluded by the auxiliary electrode 141, so that the occlusion of large-angle light rays by the auxiliary electrode 141 may be further reduced

In some specific embodiments, a plurality of light emitting devices L are arranged in an array in the first direction X and the second direction Y, two adjacent light emitting devices L arranged in the first direction correspond to different light emitting colors, and two adjacent light emitting devices L arranged in the second direction correspond to different light emitting colors.

For example, a part of the green sub-pixels Pg on the display substrate is located in the same row as the red sub-pixel Pr, and the red sub-pixel Pr and the green sub-pixel Pg are alternately arranged in the row direction. The other part of the green sub-pixels Pg on the display substrate is located in the same row as the blue sub-pixel Pb, and the blue sub-pixel Pb and the green sub-pixel Pg are alternately arranged in the row direction.

Referring to FIG. 8 to FIG. 11, in some embodiments, a metal suppression structure 131 may be provided for four sub-pixels PX that are pairwise adjacent in the first direction X and the second direction Y. Accordingly, the auxiliary electrode 141 surrounds the metal suppression structure 131, or in other words, surrounds these four sub-pixels PX. No auxiliary electrode 141 is provided between any two of these four sub-pixels PX, so that a large-angle light ray between any two of these sub-pixels PX may not be occluded by the auxiliary electrode 141. It should be noted that in FIG. 11, an upper figure shows a schematic diagram of a large-angle light ray being occluded by the auxiliary electrode 141 corresponding to the embodiments in FIG. 5, and a lower figure shows a schematic diagram of a large-angle light ray being occluded by the auxiliary electrode 141 corresponding to the embodiments in FIG. 10.

Referring to FIG. 12 to FIG. 15, in some embodiments, a metal suppression structure 131 may be provided for nine sub-pixels PX that are pairwise adjacent in the first direction X and the second direction Y. Accordingly, the auxiliary electrode 141 surrounds the metal suppression structure 131, or in other words, surrounds these nine sub-pixels PX. No auxiliary electrode 141 is provided between any two of these nine sub-pixels PX, so that a large-angle light ray between any two of these sub-pixels PX may not be occluded by the auxiliary electrode 141. It should be noted that in FIG. 11, an upper figure shows a schematic diagram of a large-angle light ray being occluded by the auxiliary electrode 141 corresponding to the embodiments in FIG. 5, and a lower figure shows a schematic diagram of a large-angle light ray being occluded by the auxiliary electrode 141 corresponding to the embodiments in FIG. 14.

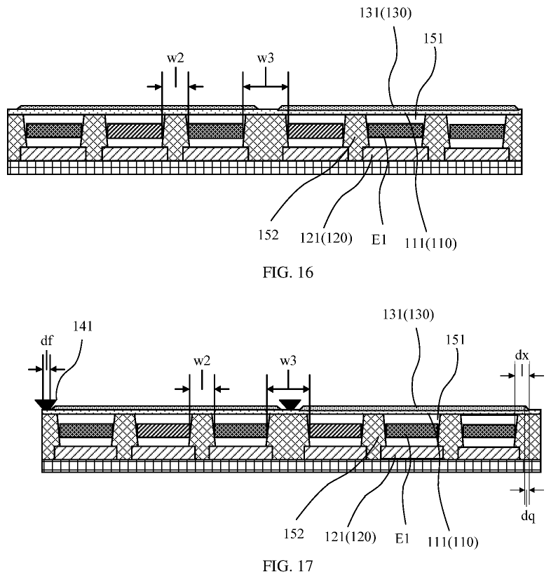

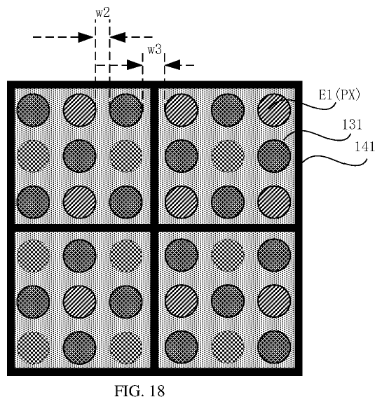

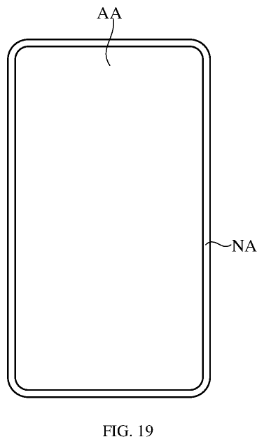

FIG. 16 schematically shows a cross-sectional view five of a metal suppression structure according to the embodiments of the present disclosure, FIG. 17 schematically shows a fifth cross-sectional view of a metal suppression structure and an auxiliary electrode according to the embodiments of the present disclosure, and FIG. 18 schematically shows a fourth plan view of a metal suppression structure and an auxiliary electrode according to the embodiments of the present disclosure.

Referring to FIG. 16 to FIG. 18, in some specific embodiments, a second distance w2 is formed between the light emitting portions E1 of two adjacent light emitting devices L in a same group of light emitting devices L, and a third distance w3 is formed between the light emitting portions E1 of two adjacent light emitting devices L in adjacent groups of light emitting devices L. The second distance w2 is less than the third distance w3.

In the embodiments of the present disclosure, the distance between two adjacent light emitting portions E1 may be defined by a size of the first defining portion 152 of the pixel defining layer 150. For example, referring to FIG. 16 to FIG. 18, when the first defining portion 152 has a large size in the horizontal direction, a large distance may be formed between two light emitting portions E1 located on both sides of the first defining portion 152 when forming the light emitting portion E1. When the first defining portion 152 has a small size in the horizontal direction, a small distance may be formed between two light emitting portions E1 located on both sides of the first defining portion 152 when forming the light emitting portion E1.

In the embodiments of the present disclosure, in this way, it is equivalent to causing a group of light emitting devices L to converge towards a center of a region where that group is located. Then, a large space may be provided between adjacent groups of light emitting devices L without changing a light emitting area of the light emitting device L, and the auxiliary electrode 141 may be formed in that space. Compared to the aforementioned embodiments, such embodiments may be implemented to form a large distance between the auxiliary electrode 141 and the light emitting portion E1 on the basis of achieving the same resistance improvement, so that the occlusion of large-angle light by the auxiliary electrode 141 may be further improved.

Exemplarily, a ratio of the second distance w2 to the third distance w3 may be set to 1:2. For example, the second distance w2 may be set to 5 μm to 20 μm, and the third distance w3 may be set to 10 μm to 40 μm.

In some specific embodiments, the size df of the surface of at least one auxiliary electrode 141 on the side close to the base substrate 100 in the width direction of the at least one auxiliary electrode 141 is less than or equal to the second distance w2. For example, the size df of the surface of the auxiliary electrode 141 on the side close to the base substrate 100 in the width direction of the auxiliary electrode 141 may be set to 1 μm to 20 μm. Therefore, compared to the aforementioned embodiments, the size df of the surface of the auxiliary electrode 141 on the side close to the base substrate 100 in the width direction of the auxiliary electrode 141 may be set larger, so that the resistance on the first electrode 111 may be reduced better.

In some specific embodiments, an edge of at least one metal suppression structure 131 overlaps with a first defining portion 152 adjacent to the at least one metal suppression structure in the thickness direction of the display substrate, and an overlapping portion has a first overlapping size dx. The first overlapping size dx is less than or equal to the size of the surface of the auxiliary electrode 141 on the side close to the base substrate 100 in the width direction of the auxiliary electrode 141. For example, the first overlapping size dx may be set to 1 μm to 10 μm.

Exemplarily, in the direction from the edge of the metal suppression structure 131 to the center of the metal suppression structure 131, the size dq of the first inclined portion 1312a is less than or equal to the first overlapping size dx. For example, the first overlapping size dx is set to 1 μm to 10 μm, and the size dq of the first inclined portion 1312a may be set to 0.1 μm to 2 μm.

Referring to FIG. 5, FIG. 10 and FIG. 14, in some specific embodiments, the display substrate includes a plurality of auxiliary electrodes 141. At least one auxiliary electrode 141 surrounds at least one metal suppression structure 131, and two adjacent auxiliary electrodes 141 share a same side edge, so that the plurality of auxiliary electrodes 141 may be formed as an integrated structure, and the resistance may be significantly reduced.

In some specific embodiments, the metal suppression structure 131 contains a metal-exclusive material, and a transmittance of the metal-exclusive material is greater than or equal to the transmittance of the first electrode. For example, the metal suppression structure 131 may contain amine, diamine, or triamine materials, such as N,N′-diphenyl-N,N′-di(9-phenyl-9H-carbazol-3-yl)biphenyl-4,4′-diamine, N-(biphenyl-4-yl)-9,9-dimethyl-N-(4-(9-phenyl-9H-carbazol-3-yl)phenyl)-9H-fluoren-2-amine, 4,4′,4″-tri(3-methylphenylphenylamino)triphenylamine, N,N′-di(1-naphthyl)-N,N′-diphenyl[1,l′-biphenyl]-4,4-diamine or 4,4′-bis[N-(3-methylphenyl)-N-phenylamino]biphenyl, N4,N4′-diphenyl-N4,N4′-bis (9-phenyl-9H-carbazol-3-yl) diphenyl-4,4′-diamine, N(diphenyl-4-yl) 9,9-dimethyl-N-(4(9-phenyl-9H-carbazol-3-yl)phenyl)-9H-fluoren-2-amine, etc.

According to the embodiments of the present disclosure, by forming the auxiliary electrode 141 using the metal suppression structure, the auxiliary electrode 141 may avoid the light emitting portion E1. The width of the side of the auxiliary electrode 141 close to the base substrate 100 may be set to 1˜20 μm, and the thickness of the auxiliary electrode 141 may be set to 5˜100 nm. By adjusting a relative positional relationship and a thickness relationship between the metal suppression structure and the auxiliary electrode 141, it is possible to accurately prepare a desired auxiliary electrode 141 to reduce a resistance value of the first electrode 111. On the basis of reducing the resistance of the first electrode 111, it is possible to reduce the influence of the auxiliary electrode 141 on a viewing angle of the light emitting device L by optimizing the width and thickness of the auxiliary electrode 141.

The metal suppression structure and the auxiliary electrode formed using the metal suppression structure in the embodiments of the present disclosure will be described below with reference to a manufacturing process of the display substrate.

In step S11, a pixel circuit, a second electrode 121, a pixel defining layer 150, a light emitting portion E1 and a first electrode 111 are formed on a clean glass substrate.

In step S12, a metal-exclusive material is evaporated above the first electrode 111 using a fine metal mask, so as to form a metal suppression structure 131. The metal-exclusive material may include amine, diamine, or triamine materials, such as N,N′-diphenyl-N,N′-di(9-phenyl-9H-carbazol-3-yl)biphenyl-4,4′-diamine, N-(biphenyl-4-yl)-9,9-dimethyl-N-(4-(9-phenyl-9H-carbazol-3-yl)phenyl)-9H-fluoren-2-amine, 4,4′,4″-tri (3-methylphenylphenylamino)triphenylamine, N,N′-di(1-naphthyl)-N,N′-diphenyl[1,1′-biphenyl]-4,4-diamine or 4,4′-bis[N-(3-methylphenyl)-N-phenylamino]biphenyl, N4,N4′-diphenyl-N4,N4′-bis(9-phenyl-9H-carbazol-3-yl) diphenyl-4,4′-diamine, N(diphenyl-4-yl)9,9-dimethyl-N-(4(9-phenyl-9H-carbazol-3-yl)phenyl)-9H-fluoren-2-amine, etc.

The metal suppression structure 131 covers the light emitting portion E1 of each light emitting device L and is disconnected above the pixel defining layer 150. The metal suppression structure 131 is in a discontinuous state between different light emitting devices, and a disconnection width dd may be set to 1˜20 μm. The thickness hj of the metal suppression structure 131 may be set to 2˜50 nm, and the metal suppression structure 131 is 1˜10 μm larger (that portion is also referred to above as the first overlapping size dx) than the pixel opening. The edge of the metal suppression structure 131 includes the first inclined portion 1312a with a width of 0.1˜2 μm, and the first angle a1 (or slope angle) is 2˜30°.

In step S13, an auxiliary electrode 141 is formed by vacuum evaporation. The auxiliary electrode 141 may be made of a metal material selected from Mg, Ag, Al, Li, K, Ca, or an alloy of the above-mentioned metal materials, such as MgxAg(1−x), LixAl(1−x), LixCa(1−x), or LixAg(1−x).

The auxiliary electrode 141 surrounds the metal suppression structure 131 and is spaced apart from the metal suppression structure 131. The auxiliary electrode 141 overlap with the metal suppression structure 131 in the thickness direction of the display substrate. The thickness hf of the auxiliary electrode 141 is set to 50˜200 nm. The cross section of the auxiliary electrode 141 in the width direction is an inverted trapezoid, that is, a top width of the auxiliary electrode 141 is greater than a bottom width of the auxiliary electrode 141. The width of the side of the auxiliary electrode 141 close to the base substrate 100 is set to 1˜15 μm, and the second angle a2 (or slope angle) of the auxiliary electrode 141 is 1˜30°.

In the display substrate manufactured by the above process, each light emitting device is provided with a corresponding metal suppression structure 131, and each metal suppression structure 131 is surrounded by the auxiliary cathode electrode 141. Optionally, a distance between the auxiliary cathode electrode 141 and an edge of the pixel opening is less than or equal to 5 μm.

In other specific embodiments, a plurality of light emitting devices L are covered by one metal suppression structure 131, so as to form an auxiliary electrode 141 surrounding the plurality of light emitting devices L, which may specifically include the following steps.

In step S21, a pixel circuit, a second electrode 121, a pixel defining layer 150, a light emitting portion E1 and a first electrode 111 are formed on a clean glass substrate.

In step S22, a metal-exclusive material is evaporated above the first electrode 111 using a fine metal mask, so as to form a metal suppression structure 131.

The metal suppression structure 131 covers the light emitting portions E1 of a group of light emitting devices L (for example, a group that includes four light emitting devices L arranged in the first direction and the second direction). The metal suppression structure 131 is disconnected between two adjacent groups of light emitting devices L, and a disconnection width dd may be set to 1˜20 μm. The thickness hj of the metal suppression structure 131 may be set to 2˜50 nm, and the metal suppression structure 131 is 1˜10 μm larger (that portion is also referred to above as the first overlapping size dx) than the pixel opening. The edge of the metal suppression structure 131 includes the first inclined portion 1312a with a width of 0.1˜2 μm, and the first angle a1 (or slope angle) is 2˜30°.

In step S23, an auxiliary electrode 141 is formed by vacuum evaporation. The auxiliary electrode 141 surrounds the metal suppression structure 131 and is spaced apart from the metal suppression structure 131. The auxiliary electrode 141 overlaps with the metal suppression structure 131 in the thickness direction of the display substrate. The thickness hf of the auxiliary electrode 141 is set to 50˜200 nm. The cross section of the auxiliary electrode 141 in the width direction is an inverted trapezoid, that is, a top width of the auxiliary electrode 141 is greater than a bottom width of the auxiliary electrode 141. The width of the side of the auxiliary electrode 141 close to the base substrate 100 is set to 1˜15 μm, and the second angle a2 (or slope angle) of the auxiliary electrode 141 is 1˜30°.

In the display substrate manufactured by the above process, one metal suppression structure 131 coves four light emitting devices, then the occlusion of large-angle light ray of the light emitting device by the auxiliary electrode 141 may be reduced, and the viewing angle may be improved.

In other specific embodiments, it is also possible to form a metal suppression structure 131 that covers a plurality of light emitting devices L, which may specifically include the following steps.

In step S31, a pixel circuit, a second electrode 121, a pixel defining layer 150, a light emitting portion E1 and a first electrode 111 are formed on a clean glass substrate.

In step S32, a metal-exclusive material is evaporated above the first electrode 111 using a fine metal mask, so as to form a metal suppression structure 131.

The metal suppression structure 131 covers the light emitting portions E1 of a group of light emitting devices L (for example, a group that includes nine light emitting devices L arranged in the first direction and the second direction). The metal suppression structure 131 is disconnected between two adjacent groups of light emitting devices L, and a disconnection width dd may be set to 1˜20 μm. The thickness hj of the metal suppression structure 131 may be set to 2˜50 nm, and the metal suppression structure 131 is 1˜10 μm larger (that portion is also referred to above as the first overlapping size dx) than the pixel opening. The edge of the metal suppression structure 131 includes the first inclined portion 1312a with a width of 0.1˜2 μm, and the first angle a1 (or slope angle) is 2˜30°.

In step S33, an auxiliary electrode 141 is formed by vacuum evaporation. The auxiliary electrode 141 surrounds the metal suppression structure 131 and is spaced apart from the metal suppression structure 131. The auxiliary electrode 141 overlaps with the metal suppression structure 131 in the thickness direction of the display substrate. The thickness hf of the auxiliary electrode 141 is set to 50˜200 nm. The cross section of the auxiliary electrode 141 in the width direction is an inverted trapezoid, that is, a top width of the auxiliary electrode 141 is greater than a bottom width of the auxiliary electrode 141. The width of the side of the auxiliary electrode 141 close to the base substrate 100 is set to 1˜15 μm, and the second angle a2 (or slope angle) of the auxiliary electrode 141 is 1˜30°.

In the display substrate prepared by the above process, the metal suppression structure 131 coves nine light emitting devices L, then the occlusion of large-angle light ray of the light emitting device by the auxiliary electrode 141 may be reduced, and the viewing angle may be improved.

In other specific embodiments, an auxiliary electrode 141 having a small thickness may be formed, which specifically includes the following steps.

In step S41, a pixel circuit, a second electrode 121, a pixel defining layer 150, a light emitting portion E1 and a first electrode 111 are formed on a clean glass substrate.

In step S42, a metal-exclusive material is evaporated above the first electrode 111 using a fine metal mask, so as to form a metal suppression structure 131.

The metal suppression structure 131 covers the light emitting portions E1 of a group of light emitting devices L (for example, a group that includes one or more light emitting devices L). The metal suppression structure 131 is disconnected between two adjacent groups of light emitting devices L, and a disconnection width dd may be set to 1˜20 μm. The thickness hj of the metal suppression structure 131 may be set to 50˜100 nm, and the metal suppression structure 131 is 1˜10 μm larger (that portion is also referred to above as the first overlapping size dx) than the pixel opening. The edge of the metal suppression structure 131 includes the first inclined portion 1312a with a width of 0.3˜3 μm, and the first angle a1 (or slope angle) is 5˜50°.

In step S43, an auxiliary electrode 141 is formed by vacuum evaporation. The auxiliary electrode 141 surrounds the metal suppression structure 131 and is spaced apart from the metal suppression structure 131. The auxiliary electrode 141 does not overlap with the metal suppression structure 131 in the thickness direction of the display substrate. The thickness hf of the auxiliary electrode 141 is set to 5˜20 nm. The cross section of the auxiliary electrode 141 in the width direction is an inverted trapezoid, that is, a top width of the auxiliary electrode 141 is greater than a bottom width of the auxiliary electrode 141. The width of the side of the auxiliary electrode 141 close to the base substrate 100 is set to 1˜15 μm, the second angle a2 (or slope angle) of the auxiliary electrode 141 is 5˜30°, and the edge of the auxiliary electrode 141 is 3˜10 μm away from the edge of the light emitting portion E1.

In the display substrate manufactured by the above process, the thickness hj of the metal suppression structure 131 is greater than the thickness hf of the auxiliary electrode 141. The metal suppression structure 131 has a stronger mutual exclusion from metal, so that there is no overlap between the metal suppression structure 131 and the auxiliary electrode 141 in the vertical direction, then the auxiliary electrode 141 has a smaller width, and the distance between the edge of the auxiliary electrode 141 and the light emitting portion E1 increases, so that the occlusion of large-angle light ray by the auxiliary electrode 141 may be reduced. In addition, since the thickness hf of the auxiliary electrode 141 is reduced to below 20 nm, the transmittance of the auxiliary electrode 141 may increase, which may also help reduce the occlusion of large-angle light ray.

In other specific embodiments, it is also possible to adjust the distance between light emitting devices when adjusting the pattern size and film thickness of the metal suppression structure 131. For a width (<20 μm) of a narrow pixel defining layer of a high-resolution display device (500>PPI>200 ppi), the adjustment of the distance between light emitting devices is beneficial to a layout of the auxiliary electrode 141 without affecting existing devices or wires. In addition, it is also possible to increase the distance between the auxiliary electrode 141 and the edge of the light emitting device, which has the effect of improving the viewing angle. Therefore, it is possible to adjust the width of the pixel defining layer 150 while adjusting the pattern size and film thickness of the metal suppression structure 131, so as to reserve a wider region for the auxiliary electrode 141, thereby achieving the preparation of the auxiliary electrode 141 or improving the viewing angle. The above may specifically include the following steps.

In the embodiments of the present disclosure, pixel defining layers 150 having different widths are formed, and an auxiliary electrode 141 is formed on a pixel defining layer 150 having a larger width. Specifically, the manufacturing process includes the following steps.

In step S51, a pixel circuit, a second electrode 121, a pixel defining layer 150, a light emitting portion E1 and a first electrode 111 are formed on a clean glass substrate.

In step S52, a metal-exclusive material is evaporated above the first electrode 111 using a fine metal mask, so as to form a metal suppression structure 131.

The metal suppression structure 131 covers the light emitting portions E1 of a group of light emitting devices L (for example, a group that includes one or more light emitting devices L). The metal suppression structure 131 is disconnected between two adjacent groups of light emitting devices L, and a disconnection width dd may be set to 1˜20 μm. The thickness hj of the metal suppression structure 131 may be set to 2˜100 nm, and the metal suppression structure 131 is 3˜10 μm larger (that portion is also referred to above as the first overlapping size dx) than the pixel opening. The edge of the metal suppression structure 131 includes the first inclined portion 1312a with a width of 0.1˜2 μm, and the first angle a1 (or slope angle) is 2˜50°. A distance between two adjacent light emitting devices L in two adjacent groups is greater than a distance between two adjacent light emitting devices L in a same group. For example, the distance between two adjacent light emitting devices L in a same group may be set to 5˜20 μm, and the distance between two adjacent light emitting devices L in two adjacent groups may be set to 10˜40 μm.

In step S53, an auxiliary electrode 141 is formed by vacuum evaporation. The auxiliary electrode 141 surrounds the metal suppression structure 131 and is spaced apart from the metal suppression structure 131. The auxiliary electrode 141 does not overlap with the metal suppression structure 131 in the thickness direction of the display substrate. The thickness hf of the auxiliary electrode 141 is set to 5˜100 nm. The cross section of the auxiliary electrode 141 in the width direction is an inverted trapezoid, that is, a top width of the auxiliary electrode 141 is greater than a bottom width of the auxiliary electrode 141. The width of the side of the auxiliary electrode 141 close to the base substrate 100 is set to 1˜20 μm, the second angle a2 (or slope angle) of the auxiliary electrode 141 is 2˜50°, and the edge of the auxiliary electrode 141 is 3˜15 μm away from the edge of the light emitting portion E1.

In the display substrate manufactured by the above process, the metal suppression structure 131 covers nine light emitting devices L, and the auxiliary electrode 141 is located above the first defining portion 151 having a larger width.

Through the above methods, it is possible to prepare an auxiliary electrode 141 outside the pixel opening by using the metal suppression structure 131, and it is possible to accurately prepare an auxiliary electrode 141 that meets various requirements by adjusting a relative positional relationship between the pixel defining layer 150, the light emitting device L, the metal suppression structure 131 and the auxiliary electrode 141 and a thickness relationship between the metal suppression structure 131 and the auxiliary electrode 141, so that the resistance value of the first electrode 111 may be reduced.

At least some embodiments of the present disclosure further provide a display panel. FIG. 19 schematically shows a plan view of a display panel according to the embodiments of the present disclosure. Referring to FIG. 19, the display panel includes the above-mentioned display substrate. The display panel has the display region AA, the peripheral region NA, and related structures therein. For example, the display panel may be a liquid crystal display panel or an OLED display panel.

It should be understood that the display panel according to the embodiments of the present disclosure has all features and advantages of the above-mentioned display substrate. The details may be referred to the above descriptions and will not be repeated here.

At least some embodiments of the present disclosure further provide a display device. The display device may include any apparatus or product having a display function. For example, the display device may be a smart phone, a mobile phone, an e-book reader, a desktop personal computer (PC), a laptop PC, a netbook PC, a personal digital assistant (PDA), a portable multimedia player (PMP), a digital audio player, a mobile medical apparatus, a camera, a wearable apparatus (such as a head-mounted apparatus, electronic clothing, electronic bracelet, electronic necklace, electronic accessory, electronic tattoo, or smart watch), a television, etc.

It should be understood that the display device according to the embodiments of the present disclosure has all features and advantages of the above-mentioned display substrate. The details may be referred to the above descriptions and will not be repeated here.

Although some embodiments of the general technical concept of the present disclosure have been illustrated and explained, those ordinary skilled in the art may understand that changes may be made to those embodiments without departing from the principle and spirit of the general technical concept. The scope of the present disclosure is defined by the claims and their equivalents.

1. A display substrate, comprising:
a base substrate;
a light emitting functional layer provided on the base substrate;
a first electrode layer provided on a side of the light emitting functional layer away from the base substrate;
a metal suppression layer provided on a side of the first electrode layer away from the base substrate;
an auxiliary electrode layer provided on a side of the first electrode layer away from the base substrate; and
a light emitting device provided on the base substrate;
wherein the light emitting device comprises a light emitting portion and a first electrode located in the first electrode layer;
the metal suppression layer comprises a metal suppression structure, and an orthographic projection of the light emitting portion on the base substrate is located within an orthographic projection of the metal suppression structure on the base substrate; and
the auxiliary electrode layer comprises an auxiliary electrode electrically connected to the first electrode and spaced apart from the metal suppression structure.

2. The display substrate according to claim 1, wherein the light emitting functional layer comprises a pixel defining layer, the pixel defining layer comprises a pixel opening and a first defining portion surrounding the pixel opening, and the light emitting portion of the light emitting device is located in the pixel opening; and
wherein the auxiliary electrode at least partially surrounds the metal suppression structure, and an orthographic projection of the auxiliary electrode on the base substrate is located within an orthographic projection of the first defining portion on the base substrate.

3. The display substrate according to claim 2, wherein the metal suppression structure comprises a first middle portion and a first edge portion surrounding the first middle portion, and the first edge portion overlaps with the first defining portion in a thickness direction of the display substrate; and
wherein a thickness of the auxiliary electrode is greater than or equal to a thickness of the metal suppression structure, and the auxiliary electrode overlaps at least partially with the first edge portion in the thickness direction of the display substrate.

4. The display substrate according to claim 3, wherein a ratio of the thickness of the auxiliary electrode to the thickness of the metal suppression structure is in a range from 1:1 to 100:1.

5. The display substrate according to claim 2, wherein the metal suppression structure comprises a first middle portion and a first edge portion surrounding the first middle portion, and the first edge portion overlaps with the first defining portion in a thickness direction of the display substrate; and
wherein a thickness of the auxiliary electrode is less than a thickness of the metal suppression structure, and the auxiliary electrode is spaced apart from the first edge portion in the thickness direction of the display substrate

6. The display substrate according to claim 5, wherein a ratio of the thickness of the auxiliary electrode to the thickness of the metal suppression structure is in a range from 1:20 to 2:5.

7. The display substrate according to claim 3, wherein the first edge portion comprises a first inclined portion, a first angle is formed between a surface of the first inclined portion on a side away from the base substrate and the first electrode, a second angle is formed between a surface adjacent to the first inclined portion of the auxiliary electrode and the first electrode, and the first angle is substantially the same as the second angle.

8. The display substrate according to claim 1, wherein a cross-sectional shape of the metal suppression structure in a direction perpendicular to the base substrate comprises a trapezoid or an inverted trapezoid.

9. The display substrate according to claim 1, wherein a thickness of the auxiliary electrode is negatively correlated with a thickness of the metal suppression structure, a first distance is formed between an orthographic projection of the auxiliary electrode on the base substrate and the orthographic projection of the light emitting portion on the base substrate, and the first distance is positively correlated with the thickness of the metal suppression structure.

10. The display substrate according to claim 1, wherein the display substrate comprises a plurality of light emitting devices, the metal suppression layer comprises a plurality of metal suppression structures, at least one metal suppression structure corresponds to at least one light emitting device, and different metal suppression structures correspond to different light emitting devices;
an orthographic projection of at least one metal suppression structure on the base substrate covers an orthographic projection of the light emitting portion of the light emitting device corresponding to the at least one metal suppression structure on the base substrate; and
different metal suppression structures are spaced apart from each other.

11. The display substrate according to claim 10, wherein the plurality of light emitting devices comprise a plurality of groups, at least one group comprises a plurality of light emitting devices, and at least one metal suppression structure corresponds to at least one group of light emitting devices; and
wherein the orthographic projection of at least one metal suppression structure on the base substrate continuously covers an orthographic projection of the light emitting portion of each light emitting device in a group of light emitting devices corresponding to the at least one metal suppression structure on the base substrate.

12. The display substrate according to claim 11, wherein the plurality of light emitting devices in at least one group of light emitting devices are arranged in a first direction, and two adjacent light emitting devices arranged in the first direction correspond to different light emitting colors.

13. The display substrate according to claim 11, wherein the plurality of light emitting devices in at least one group of light emitting devices are arranged in an array in a first direction and a second direction, two adjacent light emitting devices arranged in the first direction correspond to different light emitting colors, and two adjacent light emitting devices arranged in the second direction correspond to different light emitting colors.

14. The display substrate according to claim 11, wherein a second distance is formed between the light emitting portions of two adjacent light emitting devices in a same group of light emitting devices, a third distance is formed between the light emitting portions of two adjacent light emitting devices in adjacent groups of light emitting devices, and the second distance is less than the third distance.

15. The display substrate according to claim 14, wherein a size of a surface of at least one auxiliary electrode on a side close to the base substrate in a width direction of the at least one auxiliary electrode is less than or equal to the second distance, and the widthfirst direction comprises a direction from the auxiliary electrode to the light emitting portion adjacent to the auxiliary electrode.

16. The display substrate according to claim 10, wherein an edge of at least one metal suppression structure overlaps with a first defining portion adjacent to the at least one metal suppression structure in the thickness direction of the display substrate, and an overlapping portion has a first overlapping size; and
the first overlapping size is less than or equal to a size of a surface of the auxiliary electrode on a side close to the base substrate in a width direction of the auxiliary electrode.

17. The display substrate according to claim 10, wherein the display substrate comprises a plurality of auxiliary electrodes, at least one auxiliary electrode surrounds at least one metal suppression structure, and two adjacent auxiliary electrodes share a same side edge.

18. The display substrate according to claim 1, wherein the metal suppression structure contains a metal-exclusive material, and a transmittance of the metal-exclusive material is greater than or equal to a transmittance of the first electrode.

19. A display panel, comprising the display substrate according to claim 18.

20. A display device, comprising the display panel according to claim 19.
